(19) United States
(12) Patent Application Publication
(10) Pub. No.: US 2020/0409398 A1
(43) Pub. Date: Dec. 31, 2020

(54) DEVICE, SYSTEM AND METHOD FOR PROVIDING MICROCHANNELS WITH POROUS SIDEWALL STRUCTURES

(71) Applicant: Intel Corporation, Santa Clara, CA (US)

(72) Inventors: Betsegaw Gebrehiwot, Chandler, AZ (US); Shankar Devasenathipathy, Tempe, AZ (US); Zhimin Wan, Chandler, AZ (US); Hardikkumar Prajapati, Chandler, AZ (US)

(73) Assignee: Intel Corporation, Santa Clara, CA (US)

(21) Appl. No.: 16/452,280

(22) Filed: Jun. 25, 2019

(51) Int. Cl. G05D 23/185; H01L 23/373; H01L 23/473

(52) U.S. Cl. CPC G05D 23/1858; H01L 21/76831; H01L 23/473; H01L 23/3733

(57) ABSTRACT

Techniques and mechanisms for enabling a flow of fluid through microchannels of a fluid conduit, which is thermally coupled to cool integrated circuitry. In an embodiment, sidewall structures of the fluid conduit extend from a base structure to form at least in part microchannels, which extend along the base structure. The sidewall structures accommodate a flow of a coolant fluid through the fluid conduit, where the flow in turn facilitates conduction of heat, which has been transferred to the fluid conduit from the integrated circuitry. The sidewall structures comprise pores, which extend through a corresponding sidewall structure between two microchannel regions. In another embodiment, a sidewall structure provides a gradient of average porosity along one or more dimensions.

### BACKGROUND

### 1. Technical Field

This disclosure generally relates to the field of electronic devices and more particularly, but not exclusively, to cooling of electronics using microchannels formed with porous sidewalls.

### 2. Background Art

During operation, integrated circuits, such as microprocessors, develop considerable heat. When such heating becomes excessive, it tends to impact device performance, or even result in device malfunction. Some existing techniques for cooling integrated circuits variously use narrow channels (known as “microchannels”) which are close to or formed in a die. When an array of such microchannels is situated atop a heat generating integrated circuit, the circulation of a fluid coolant such as water through the microchannels is effective to dissipate heat from the integrated circuit.

However, these existing techniques are impacted when, over time, microchannels become clogged by particles. When one or more particles become lodged in a given microchannel, fluid flow in the microchannel is prevented or otherwise reduced. This reduced flow limits thermal performance of the microchannel, which in turn contributes to heating of circuitry which would otherwise be cooled by the microchannel.

As integrated circuits advance in complexity and operating rate, the heat generated in integrated circuits during operation increases and the demands on cooling systems also escalate. Therefore, there is expected to be an increasing premium placed on solutions for cooling integrated circuitry.

### BRIEF DESCRIPTION OF THE DRAWINGS

The various embodiments of the present invention are illustrated by way of example, and not by way of limitation, in the figures of the accompanying drawings and in which:

FIG. 1A illustrates a cross-sectional side view of a system to enable cooling of integrated circuitry according to an embodiment.

FIG. 1B illustrates a cross-sectional top-side view of a fluid conduit comprising porous sidewall structures according to an embodiment.

FIG. 2 illustrates a flow diagram showing features of a method to facilitate cooling of integrated circuitry according to an embodiment.

FIG. 3 illustrates a perspective view of a system to generate porous sidewall structures of a fluid conduit according to an embodiment.

FIG. 4 illustrates a cross-sectional side view of a system to generate porous sidewall structures of a fluid conduit according to an embodiment.

FIGS. 5A through 5C variously illustrate cross-sectional views each of a respective fluid conduit according to a corresponding embodiment.

FIG. 6 illustrates a cross-sectional side view of a device to regulate the temperature of circuitry according to an embodiment.

FIGS. 7A and 7B each illustrate cross-sectional side views each of a respective device to regulate the temperature of circuitry according to a corresponding embodiment.

FIG. 8 illustrates a functional block diagram of a system to provide a flow of fluid through a fluid conduit according to an embodiment.

FIG. 9 illustrates a functional block diagram showing features of a computing device in accordance with one embodiment.

FIG. 10 illustrates a functional block diagram showing features of an exemplary computer system, in accordance with one embodiment.

### DETAILED DESCRIPTION

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including a cooling system to regulate a temperature of circuitry.

In the following description, numerous details are discussed to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

It is pointed out that those elements of the figures having the same reference numbers (or names) as the elements of any other figure can operate or function in any manner similar to that described, but are not limited to such.

Embodiments discussed herein variously provide techniques and mechanisms for improving a flow of fluid through microchannels, where the fluid facilitates cooling of integrated circuitry and/or other such structures. Some embodiments variously provide a sidewall structure which extends between, and defines at least in part, two adjoining microchannel regions which are variously configured to accommodate a flow of coolant fluid. The sidewall structure forms pores which variously extend through to each of the adjoining microchannel regions. Pores formed by a given sidewall structure each extend only partially along a vertical span of the sidewall structure, and only partially along a horizontal span of the sidewall structure. For example, a vertical (z-axis) span of a given pore is less than a vertical height of the sidewall structure which forms the pore—e.g., where a bottom of a pore is vertically offset from a bottom of the sidewall structure and/or a top of the pore is vertically offset from a top of the sidewall structure. Accordingly, a cross-sectional area of a given pore is smaller than (e.g., less than one quarter of and, in some embodiments, less than one-tenth of) a cross-sectional area of one of the first microchannel or the second microchannel.

In so providing a porous sidewall material, some embodiments variously enable a lateral transfer of coolant fluid—through a sidewall structure—between two microchannels. Such a transfer is provided, for example, when fluid flow along the length of one such microchannel is otherwise inhibited (e.g., prevented) by one or more particles clogging said microchannel. Accordingly, some embodiments mitigate the possibility of fluid being stagnant in a given microchannel as a result of such clogging—e.g., where such stagnant fluid would otherwise be susceptible to heating that, over time, compromises the performance of a circuit cooling system.

As used herein, “fluid conduit” (or simply “conduit”) refers to any of various combinations of structures which provide an at least partially enclosed chamber and microchannels disposed therein. For example, such a chamber includes a base structure (e.g., a base plate) to facilitate heat transfer between the chamber and a region which is external to the fluid conduit, where sidewall structures variously extend from a floor surface of the base structure. In various embodiments, a fluid conduit further comprises inlet structures and/or outlet structures to variously accommodate fluid flow through the fluid conduit. Certain features of some embodiments are variously described herein with reference to a given xyz coordinate system, wherein the length, width and height of a given microchannel correspond (respectively) to the x-axis, y-axis, and z-axis of such a xyz-coordinate system.

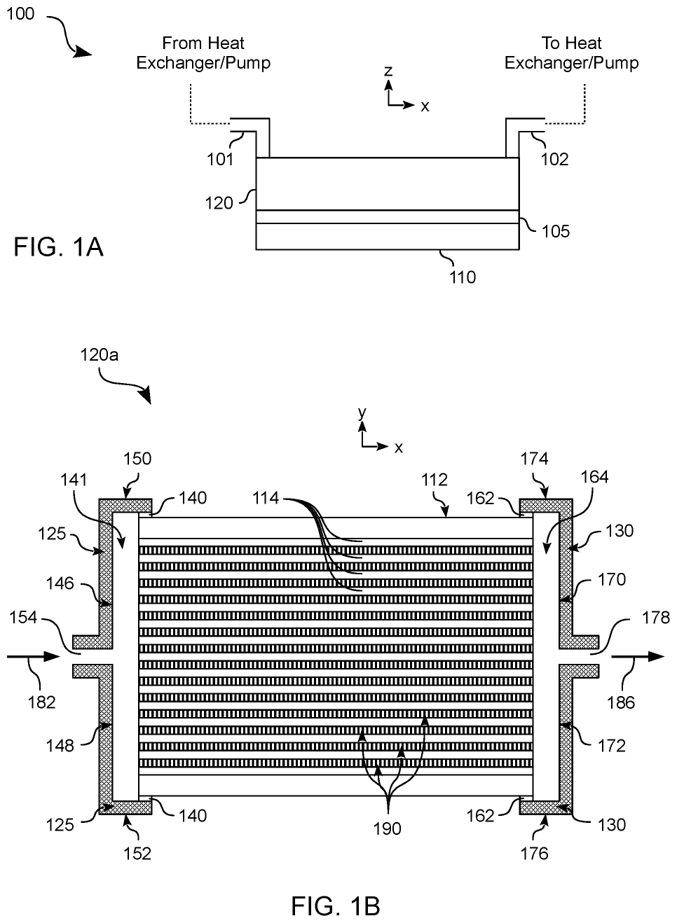

FIG. 1A is a functional block diagram illustrating a cross-sectional side view of a system 100 to provide thermal regulation of integrated circuitry according to an embodiment. System 100 is one example of an embodiment wherein microchannels (to be used for convective heat transfer with a coolant fluid) are formed at least in part by one or more sidewall structures, where some or all such sidewall structures variously form pores placing adjacent microchannels in fluid communication such that fluid flow may occur between a respective two microchannels.

As shown in FIG. 1A, system 100 comprises an integrated circuit (IC) 110 and a fluid conduit 120 which is thermally coupled thereto. In the example embodiment of system 100, IC 110 is coupled to fluid conduit 120 via a thermal interface material (TIM)—e.g., wherein IC 110 comprises one or more of a central processing unit, a graphics processor, a memory controller, a memory device, one or more interconnects (e.g., including one or more busses) and/or the like.

In some embodiments, system 100 omits TIM 105—e.g., where a cold plate structure of fluid conduit 120 is thermally coupled to IC 110 directly. In some embodiments, a rear side of IC 110 is thinned to reduce thermal resistance between IC 110 and fluid conduit 120, which (for example) is coupled to the rear side of the IC 110. In other embodiments, system 100 further comprises a package mold, another TIM and/or other thermally conductive structures (not shown) which are disposed between, and facilitate thermal coupling of, IC 110 and fluid conduit 120.

To facilitate thermal regulation of system 100, fluid conduit 120 supports coupling to receive a coolant fluid (not separately shown)—e.g., via the illustrative inlet port 101 shown. A flow of such a fluid through fluid conduit 120 is provided, for example, with a pump (not shown) which is to be coupled to—or alternatively, is a component of—system 100. During an operation of system 100, heat is transferred from IC 110 to the coolant fluid, which then leaves via a flow of the coolant fluid from fluid conduit 120. For example, the coolant fluid exits from the fluid conduit 120 via an outlet port 102 and is circulated to a heat exchanger (not shown) and then to a pump (not shown). In one such embodiment, the heat exchanger includes a length of tube with heat-conductive fins (not shown) mounted thereon and a fan (not shown) to direct air through the fins. Heat which is transferred to the coolant fluid in fluid conduit 120 is subsequently dissipated with the heat exchanger. After passing through the heat exchanger and the pump, the coolant fluid flows back to fluid conduit 120 via inlet port 101.

In some embodiments, microchannels of fluid conduit 120 are formed at least in part by porous sidewall structures which variously extend (e.g., length-wise along the x-axis dimension shown) each between a respective two adjoining microchannel regions. Respective first ends of the microchannels are coupled to an inlet, such as inlet port 101, and respective second ends of the microchannels are coupled to an outlet such as outlet port 102. The microchannels are configured to convey, over a base structure of fluid conduit 120, a fluid to remove heat which has been transferred to fluid conduit 120 from IC 110.

An example of one such embodiment, which is illustrated in FIG. 1B, is a fluid conduit 120a comprising porous sidewall structures to enable a communication of fluid between microchannels according to an embodiment. Fluid conduit 120a is one example of a device, according to an embodiment, which facilitates thermal coupling to integrated circuitry, where the device facilitates a flow of a fluid for cooling such integrated circuitry. In some embodiments, fluid conduit 120a includes features of fluid conduit 120 (for example).

As shown in FIG. 1B, fluid conduit 120a includes a base structure 112 and microchannels 114 which are variously extend from (e.g., are formed in, bonded to, or otherwise disposed on) a surface of base structure 112. Microchannels 114 are passages which variously accommodate a flow of fluid therein. Such passages are defined at least in part by porous sidewall structures 190 which, for example, variously extend (e.g., length-wise along the x-axis dimension shown) each between a respective two adjoining ones of microchannels 114. For a given one of microchannels 114, a width (y-axis dimension) of the microchannel is in a range of 10 micrometers (μm) to 2000 μm, for example—e.g., where the width is in a range of 200 μm to 600 μm. Alternatively or in addition, a length (x-axis dimension) of such a microchannel is in a range of 1 mm to 200 mm and, in some embodiments, in a range of 5 mm to 60 mm, for example. In one such embodiment, a height (z-axis dimension) of the microchannel is in a range of 5 μm to 5000 μm and, in some embodiments, in a range of 10 μm to 1000 μm, for example. However, some embodiments are not so limited with respect to one or more such microchannel dimensions, which differ across such embodiments according to implementation-specific details.

In some embodiments, sidewall structures 190 comprise copper, aluminum, aluminum nitride, and/or any of various other materials which are suitable to accommodate sintering, laser melting or other such processing to form pore structures. In one such embodiment, for a given one of sidewall structures 190, a width (y-axis dimension) of the sidewall structure is in a range of 20 μm to 2000 μm (and in some embodiments, in a range of 100 μm to 1000 μm, for example). The length and height of such a sidewall structure are equal to the length and height (respectively) of an adjoining sidewall region, for example. Alternatively or in addition, a porosity of such a sidewall structure is in a range of 3% to 95% and, in some embodiments, in a range of 5% to 50%, for example. In this particular context, porosity refers to a characteristic of a given section of a sidewall structure, where the porosity of the section in question is equal to a ratio of a total volume of the pores of the section to a total volume of the entire section.

Microchannels 114 are, but need not, all be straight and parallel to each other. The particular number of microchannels 114 is merely illustrative, and fluid conduit 120a comprises more or fewer microchannels, in various embodiments. In general, structures variously represented in FIGS. 1A and 1B and/or the other drawings herein are not necessarily to scale.

In an embodiment, fluid conduit 120a also includes a lid structure (not shown) that effectively closes a top of the microchannels 114 which extend from base structure 112. Fluid conduit 120a further includes an inlet manifold member 125 and an outlet manifold member 130. Inlet manifold member 125 is coupled to a front end of base structure 112 and, for example, also to the corresponding end of the lid structure. The coupling of inlet manifold member 125 to base structure 112 and the lid structure is done, for example, by a liquid-tight sealing arrangement 140, such as an O-ring, solder or an epoxy adhesive.

Inlet manifold member 125 includes a plurality of walls to define an inlet manifold 141 at the front end of base structure 112. The inlet manifold is in communication with some or all of microchannels 114. By way of illustration and not limitation, a plurality of walls that constitute inlet manifold member 125 includes a main side wall indicated at 146, 148. The plurality of walls also includes a left side wall 150 and a right side wall 152. It will be understood that all of the main side wall, left side wall 150 and right side wall 152 are to be considered “vertical walls”—e.g., where the vertical direction corresponds to the z-axis dimension shown in FIG. 1A.

The main side wall has an inlet port 154—inlet port 101, for example—formed therein (e.g., at a central location in the main side wall) to allow coolant (not shown) to flow into inlet manifold 141. Inlet port 154 is integrally formed in the main side wall, or is formed by molding the main side wall around a suitable fitting, which is not separately shown. Inlet port 154 is configured to facilitate connection of a coolant line, not shown in FIG. 1B, which transports coolant from a pump (not shown) to fluid conduit 120a. In some embodiments, inlet manifold member 125 further comprises horizontal top and bottom walls (not shown) which variously extend over (or under) inlet manifold 141 at least in part—e.g., wherein inlet manifold member 125 forms at least part of the lid structure which extends over microchannels 114. In some embodiments, inlet manifold member 125 is formed as a single unitary body, formed for example, of a metal such as copper, silicon, or molded plastic.

A similar sealing arrangement (indicated at 162) is employed, for example, for outlet manifold member 130, as described herein in connection with inlet manifold member 125. In some embodiments, the outlet manifold member 130 is a mirror image of inlet manifold member 125, or even identical in form to inlet manifold member 125. Outlet manifold member 130 includes a plurality of walls to define an outlet manifold 164 at the rear end of base structure 112. The outlet manifold 164 is in communication with all of microchannels 114. The plurality of walls that constitute outlet manifold member 130 includes a main side wall indicated at 170, 172. The plurality of walls that constitute outlet manifold member 130 also includes a left side wall 174 and a right side wall 176. The main side wall and right and left side walls of outlet manifold member 130 are all vertical walls.

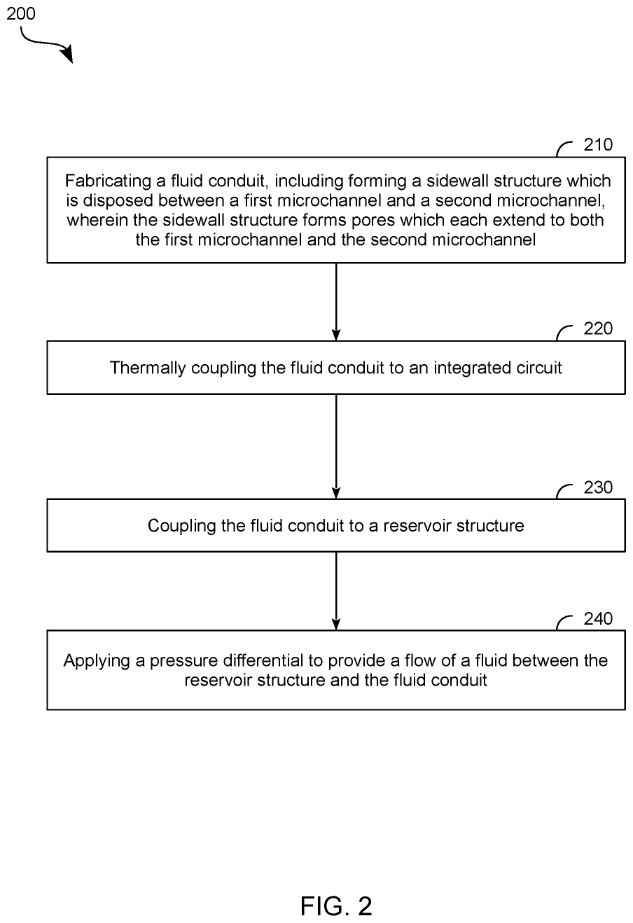

The main side wall of outlet manifold member 130 has an outlet port 178—outlet port 102, for example—formed therein (e.g., at a central location in the main side wall) to allow coolant to flow out of outlet manifold 164. Outlet port 178 is configured to facilitate connection of a coolant line (not shown in FIGS. 1 and 2) which transports coolant from fluid conduit 120a to a pump, as described above. In some embodiments, outlet manifold member 130 further comprises horizontal top and bottom walls (not shown) which variously extend over (or under) outlet manifold 164 at least in part—e.g., wherein outlet manifold member 130 forms at least part of the lid structure which extends over microchannels 114. As was indicated with respect to inlet manifold member 125, outlet manifold member 130 is formed as a single unitary body. Outlet manifold member 130 is, but need not, be formed of the same material as inlet manifold member 125.

As shown, respective first ends of microchannels 114 (the first ends at inlet manifold 141) are coupled to receive fluid from an inlet, such as the illustrative inlet port 154 shown. Respective second ends of microchannels 114 (the second ends at outlet manifold 164) are coupled to provide the fluid to an outlet, such as the illustrative outlet port 178 shown. The microchannels 114 are configured to variously convey a fluid, in parallel over the base structure 112, between inlet port 154 and outlet port 178. For a given one of sidewall structures 190, the sidewall structure is disposed between, extends to, and defines at least in part, a respective first microchannel and second microchannel of microchannels 114. In such an embodiment, said first microchannel and second microchannel are in fluid communication with each other through one or more pores of the sidewall structure which is disposed therebetween. In an embodiment, such a sidewall structure spans a longitudinal length (between the ends of two adjoining microchannels) over base structure 112—e.g., where the sidewall structure comprises a plurality of pores over at least half of said longitudinal length.

In operation, a pump (which is not shown) pumps a liquid coolant (not shown) through an inflow coolant line (not shown) that is coupled to inlet port 154. The coolant flows through the inlet port in the direction (indicated by arrow 182) into inlet manifold 125. It will be recognized that the direction indicated by arrow 182 is a horizontal (x-y plane) direction that, for example, is parallel to a length (x-axis) dimension of microchannels 114. The coolant is distributed by inlet manifold 125 among microchannels 114 and flows out of inlet manifold 125 into microchannels 114 in the same direction indicated by arrow 182. The coolant flows through microchannels 114 in the same direction indicated by arrow 182.

While the coolant flows through microchannels 114, heat generated by transistors and/or other circuitry (not separately shown) is transferred through base structure 112 to the coolant, thereby heating the coolant. The heated coolant, still flowing in the direction indicated by the arrow 182, flows out of the microchannels 114 and into outlet manifold 164. Further, the coolant flows in the direction indicated by arrow 186 out of outlet manifold 164 via outlet port 178. In some embodiments, the coolant flows from outlet port 178 to a heat exchanger (not shown) via an outflow coolant line (not shown) that is coupled to outlet port 178. In one such embodiment, a fan (not shown) directs air flow through the heat exchanger to remove heat from the coolant, thereby cooling the coolant, which is then pumped back to fluid conduit 120a. To efficiently facilitate a transfer of heat, a coolant with a relatively high thermal conductivity and high heat capacity is used. Moreover, it is beneficial if coolant is relatively inexpensive and easy to pump. Note that water has a relatively high thermal conductivity, a relatively high heat capacity, is relatively inexpensive, and can be readily pumped.

FIG. 2 shows features of a method 200 to provide functionality of a fluid conduit according to an embodiment. Method 200 is one example of an embodiment which is to fabricate, operate, or otherwise facilitate cooling with a device (e.g., one of fluid conduits 120, 120a) which comprises microchannels formed at least in part by porous sidewall structures.

As shown in FIG. 2, method 200 includes (at 210) fabricating a fluid conduit, including forming a sidewall structure which is disposed between a first microchannel and a second microchannel, wherein the sidewall structure forms pores which each extend to both the first microchannel and the second microchannel. In some embodiments, the sidewall structure comprises one of copper, aluminum, or aluminum nitride—e.g., wherein the fabricating at 210 comprises forming sidewall structures 190. For example, forming the sidewall structure at 210 comprises, in some embodiments, sintering particles (comprising copper, aluminum and/or other suitable material) to form a unified mass, where void spaces between such particles contribute to a formation of pores which variously extend through the unified mass. Alternatively or in addition, forming the sidewall structure at 210 comprises performing a selective laser melting of a powder or other granular material.

In various embodiments, a width of the sidewall structure formed at 210 is in a range of 20 μm to 2000 μm—e.g., in a range of 100 μm to 1000 μm. Additionally or alternatively, an average porosity of such a sidewall structure is in a range of 3% to 95%—e.g., in a range of 5% to 50%. In some embodiments, porosity of a sidewall structure varies along a vertical (z-axis) span of the sidewall structure. For example, a first portion of one such sidewall structure is denser (less porous) than a second portion of said sidewall structure—e.g., where, as compared to the second portion, the first portion is closer to a base structure from which the sidewall structure extends. Accordingly, some embodiments provide a gradient of average porosity along a height (z-axis dimension) of a given sidewall structure. In providing a sidewall structure which is less porous in a region which is relatively closer to such a base structure, some embodiments facilitate fluid flow between two microchannels, while also promoting heat conduction away from the base structure and into the sidewall structure. Alternatively or in addition, some embodiments provide a gradient of average porosity along a length (x-axis dimension) of such a sidewall structure.

Additionally or alternatively, method 200 comprises operations to connect and/or operate the fluid conduit which is fabricated at 210. More particularly, method 200 further comprises (at 220) thermally coupling the fluid conduit to an integrated circuit, and (at 230) coupling the fluid conduit to a reservoir structure. By way of illustration and not limitation, the thermal coupling at 220 comprises adhering, soldering and/or otherwise bonding the fluid conduit—directly or indirectly (e.g., via one or more of a thermal interface material, heat spreader, package mold material or the like)—to an IC die. In one such embodiment, the thermal coupling enables heat transfer between fluid conduit 120 and IC 110 via TIM 105. The coupling at 230 comprises, for example, connecting the reservoir to inlet port 154, outlet port 178 and/or other such coupling structures of the fluid conduit.

Method 200 further comprises (at 240) applying a pressure differential to provide a flow of a fluid between the reservoir structure and the fluid conduit. Such a flow is provided, for example, while operation of the integrated circuit generates heat which is transferred—via radiation and/or conduction—into a chamber of the fluid conduit. A flow of the fluid, through the microchannels which are formed in the chamber, facilitates convection to remove heat from the integrated circuit.

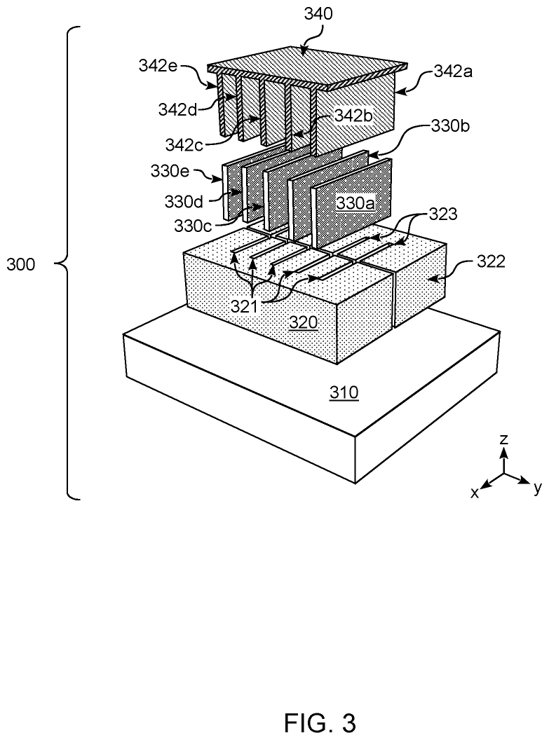

FIG. 3 shows an exploded view of a system 300 to facilitate fabrication of a fluid conduit according to an embodiment. System 300 is one example of an embodiment wherein a mold and other structures are operable to form a porous mass (which is to function as a microchannel sidewall) by sintering a copper powder or other such suitable granular material. In some embodiments, system 300 facilitates one or more operations of method 200.

As shown in FIG. 3, system 300 includes a plunger 340 and a mold which is to confine a powder (or other such particulate matter) to a space for the application of pressure thereon. In the example embodiment shown, system 300 comprises mold body portions 320, 322 which, when brought into contact with each other, form a mold that accommodates the depositing of a powder therein. By way of illustration and not limitation, voids are variously formed by an alignment of slot structures 321 (which are formed by mold body portion 320) each with a respective one of slot structures 323 which are formed by mold body portion 322. Such voids are formed over a base plate 310 which, for example, comprises copper, aluminum, or another suitable heat conductive material. In some embodiments, base plate 310 is to function as a heat transfer structure (e.g., base structure 112) of the fluid conduit, wherein sintering bonds the resulting porous sidewall structures to base plate 310. Alternatively, structures formed by sintering between plunger 340 and base plate 310 are to be subsequently removed from base plate 310 and variously adhered, bonded, or otherwise disposed on a base structure of a fluid conduit.

In the example embodiment shown, plunger 340 forms five fin structures 342a, . . . , 342e, and slot structures 321, 323 variously form five voids which are each aligned with a respective one of fin structures 342a, . . . , 342e. Particulate matter portions 330a, . . . , 330e are variously deposited each into a respective one of said voids. Particulate matter portions 330a, . . . , 330e include a metal (copper, for example) and, in some embodiments, further include a binder compound such as poly-methyl methacrylic acid. In various embodiments, particles of particulate matter portions 330a, . . . , 330e are deposited into the voids in an order which is based on the respective sizes of said particles. Such depositing provides a gradient of average particle size along a height (z-axis dimension) of a given void—e.g., wherein smaller particles are deposited into the voids before relatively larger particles. Alternatively or in addition, particles are deposited to provide a gradient of average particle size along a length (x-axis dimension) of the voids.

Subsequently, fin structures 342a, . . . , 342e are brought into the voids to apply pressure on the deposited particulate matter portions 330a, . . . , 330e. The pressure (e.g., in combination with an applied heat) results in particles of particulate matter portions 330a, . . . , 330e being variously melted or otherwise bonded together—e.g., wherein some or all particles of one of particulate matter portions 330a, . . . , 330e combine to form a single mass. A granularity of the particles contributes to a formation of pores in such a mass—e.g., where some or all such pores extend through the mass to opposite sides thereof.

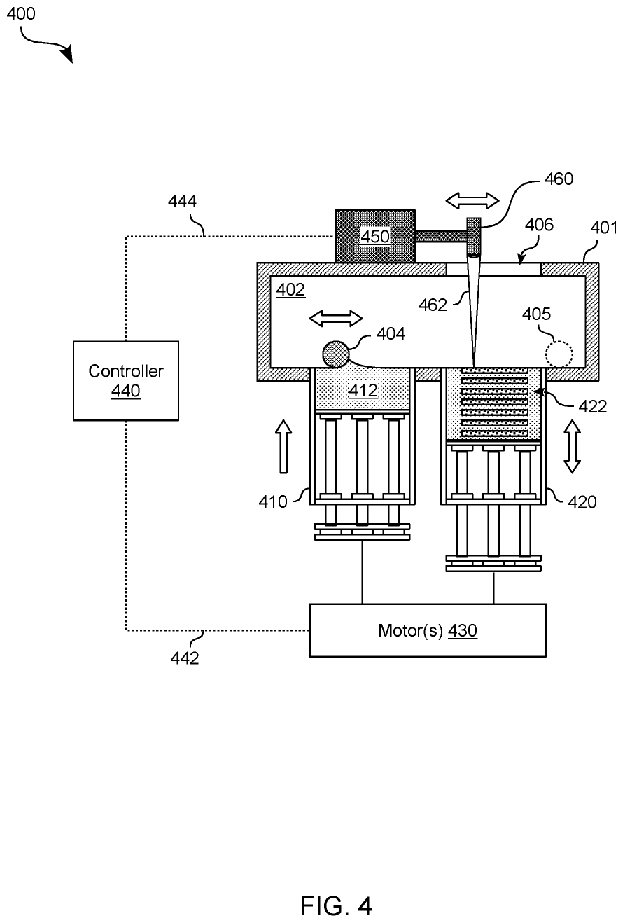

FIG. 4 shows a cross-sectional side view of a system 400 to facilitate fabrication of a fluid conduit according to an embodiment. System 400 is one example of an embodiment wherein structures are operable to form a porous mass (which is to function as a microchannel sidewall) by selective layer melting of a copper powder or other such suitable granular material. In some embodiments, system 400 facilitates one or more operations of method 200.

As shown in FIG. 4, system 400 comprises a chamber 401, an elevator mechanism 410 and an elevator mechanism 420 which are variously coupled to one another. In some embodiments, elevator mechanisms 410, 420 are variously operable each by a respective motor (as illustrated by the one or more motors 430 shown). The one or more motors 430 operate responsive to a control signal 442 from a controller 440 of system 400—e.g., wherein controller 440 comprises any of various suitable combinations of hardware and/or executing software which (for example) are adapted from conventional industrial control techniques.

In one such embodiment, controller 440 is further coupled to provide a control signal 444 to a laser positioning device 450 of system 400. Laser positioning device 450 comprises any of various gears, belts, rods and/or other hardware (e.g., including one or more rack-and-pinion mechanisms) which is operable—responsive to control signal 444—to move a laser 460 of system 400 relative to chamber 401. Laser 460 is operable to direct laser light 462 through an opening 406 of chamber 401 and into an interior space 402 which is formed by chamber 401.

In the example embodiment shown, interior space 402 is open to a reservoir 412 which has disposed therein a powder or other granular material. Interior space 402 is also open to a receptacle 422 in which one or more porous structures are to be formed by laser melting. During operation of system 400, portions of the powder in reservoir 412 are sequentially moved over to receptacle 422, where said portions are variously subjected to selective laser melting processing with laser light 462.

By way of illustration and not limitation, system 400 further comprises a roller 404 which is disposed in interior space 402. Roller 404 is operable with one or more motors and/or other such mechanisms (not shown) to sweep, spread or otherwise move a portion of the powder from reservoir 412 to receptacle 422. For example, roller 404 is operable—e.g., responsive to controller 440—to move back and forth between a region over reservoir 412 and another position, such as the illustrative position 405 shown, on an opposite side of receptacle 422. Such back and forth movement of roller 404 facilitates a distribution of successive layers of the powder over receptacle 422.

When a given portion of the powder is disposed over receptacle 422, laser 460 is variously moved by laser positioning device 450 to melt selected areas of the powder with laser light 462. By controlling such melting, various embodiments enable the formation of a porous mass which is to function as a microchannel sidewall structure. In one such embodiment, control signal 442 signals the one or more motors 430 to raise a floor structure of reservoir 412 over time using elevator mechanism 410—e.g., to facilitate the spreading of successive layers of the powder with roller 404. Alternatively or in addition, control signal 442 signals the one or more motors 430 to lower a floor structure of receptacle 422 with elevator mechanism 420—e.g., to increase the volume of receptacle 422 in order to accommodate structures which are formed by selective laser melting.

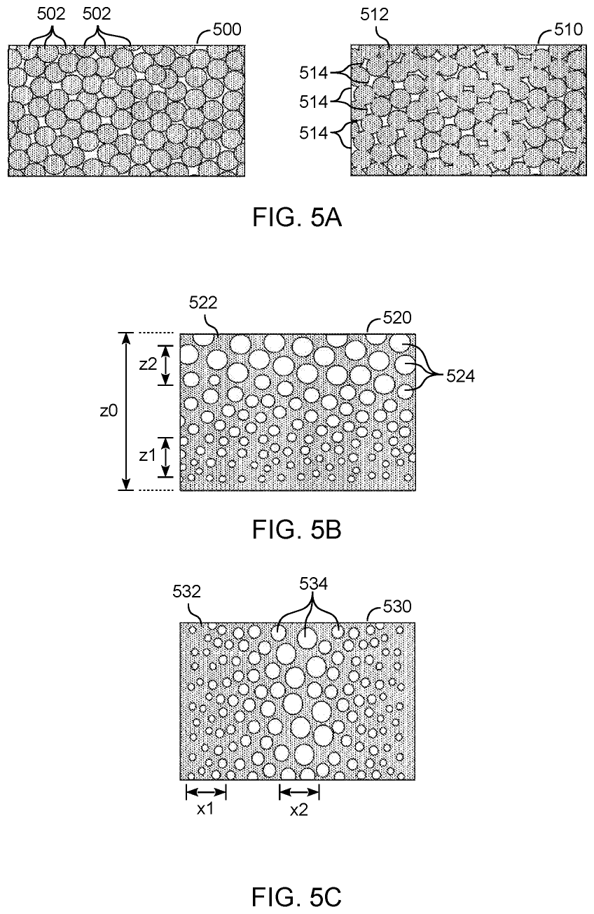

FIGS. 5A-C shows various detail views of structures which are each to provide a respective microchannel sidewall according to a corresponding embodiment. Some or all of the structures shown in FIGS. 5A-5C are variously provided, for example, with operations of method 200—e.g., where such structures are formed with one of systems 300, 400 and/or where such structures are those of porous sidewall structures 190.

FIG. 5A shows detail views 500, 510 of respective structures each during a corresponding stage of processing to fabricate a porous microchannel sidewall structure according to an embodiment. View 500 shows an initial aggregation of particles 502 (e.g., comprising copper, aluminum, aluminum nitride, and/or any of various other suitable materials) of a particulate matter which is to be subjected to sintering, melting or other such processing to form a porous mass. As shown in view 500, a granularity of the particulate matter contributes to void spaces between particles 502 prior to such processing.

As shown in view 510, processing of the aggregation which is shown in view 500 results in the formation of a unified mass 512 of particles that have been melted or otherwise bonded together. The granularity of particles 502 contributes to the formation of pore structures 514 in the mass 512. In an embodiment, at least some of these pore structures 514 variously extend through the mass 512—i.e., where said pores extend to each of a first side of a sidewall structure and a second side of the sidewall structure (wherein the first side is opposite the second side). In some embodiments, pore structures 514 facilitate a flow of a coolant fluid from one microchannel to another microchannel. In one example embodiment, an average porosity of the structure shown in view 510 is in a range of 3% to 95% (e.g., in a range of 5% to 50%).

FIG. 5B shows a detail view of a sidewall structure 520 according to another embodiment. Sidewall structure 520 illustrates one example of an embodiment which provides a porosity gradient along a height (z-axis) dimension. In the example embodiment shown, sidewall structure 520 comprises a unified mass 522 which forms pores 524 variously extending therein. A first portion of sidewall structure 520 has a first vertical span z1, and a second portion of sidewall structure 520 has a second vertical span z2 (wherein z1 and z2 are offset entirely from one another along the height dimension). The first vertical span z1 and the second vertical span z2 are, for example, each at least 10% of a total vertical span z0 of sidewall structure 520 (e.g., wherein z1 and z2 are each at least 15% of z0 and, in some embodiments, each at least 20% of z0). In some embodiments, the first portion in z1 has a first porosity, and the second portion in z2 has a second porosity which (for example) differs from the first porosity by at least 5% (e.g., wherein the first porosity is 10% and the second porosity is more than 15%). In one such embodiment, the second porosity differs from the first porosity by at least 10%—e.g., where the difference is at least 20% and, in some embodiments, at least 30%. In providing a vertical porosity gradient (e.g., wherein the porosity increases with distance from a base plate), sidewall structure 520 enables a flow of coolant between microchannels, while also promoting conduction of heat into the fluid conduit from an underlying heat source.

FIG. 5C shows a detail view of a sidewall structure 530 according to another embodiment. Sidewall structure 530 illustrates one example of an embodiment which provides a porosity gradient along a length (x-axis) dimension. In the example embodiment shown, sidewall structure 530 comprises a unified mass 532 which forms pores 534 variously extending therein. A first portion of sidewall structure 530 has a first horizontal span x1, and a second portion of sidewall structure 530 has a second horizontal span x2 (wherein x1 and x2 are offset entirely from one another along the length dimension). In some embodiments, x1 and x2 are each at least 100 μm (e.g., wherein x1 and x2 are each at least 200 μm and, in some embodiments, at least 500 μm). The first portion in x1 has a first porosity, and the second portion in x2 has a second porosity which (for example) differs from the first porosity by at least 5% (e.g., wherein the first porosity is 10% and the second porosity is more than 15%). In one such embodiment, the second porosity differs from the first porosity by at least 10%—e.g., where the difference is at least 20% and, in some embodiments, at least 30%.

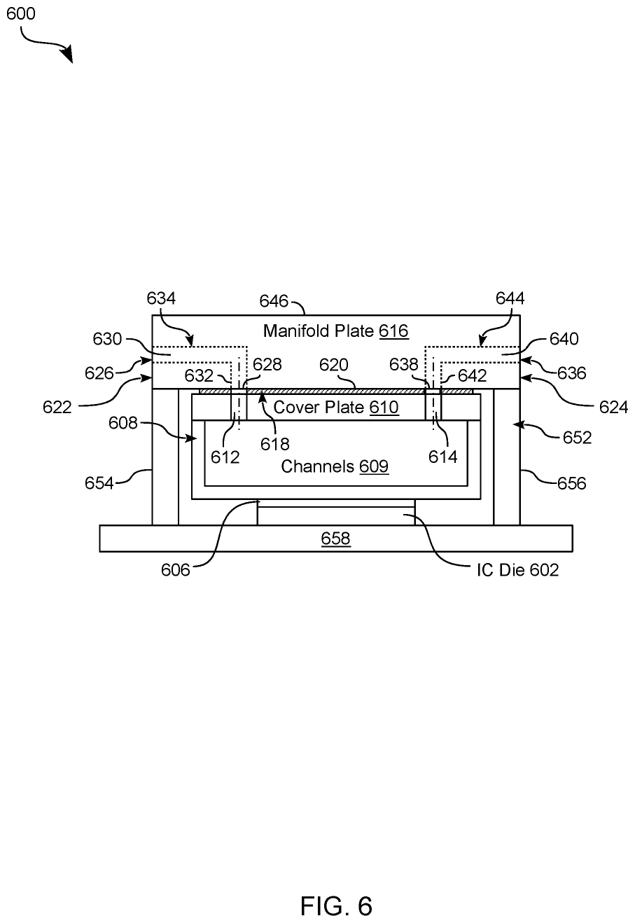

FIG. 6 shows features of a device 600 to provide thermal regulation of integrated circuitry according to an embodiment. Device 600 includes features of system 100 and/or fluid conduit 120, for example. In some embodiments, functionality of device 600 is provided by some or all operations of method 200—e.g., wherein microchannels of device 600 are fabricated using one of systems 300, 400.

As shown in FIG. 6, device 600 includes an IC die 602 (e.g., a microprocessor or “CPU” die) and a fluid conduit thermally coupled to IC die 602 by a thermal interface material (TIM) 606. The fluid conduit includes a microchannel chamber 608 which has microchannels 609 (not shown in detail) formed therein. In particular, microchannel chamber 608 defines a bottom and exterior sidewalls of microchannels 609 in which coolant is to be transported in proximity to IC die 602 for heat to be transferred to the coolant from IC die 602. Some or all of microchannels 609 are variously defined at least in part by porous sidewall structures such as any of various ones described herein.

The fluid conduit also includes a cover plate 610 positioned on (e.g., bonded to) microchannel chamber 608 to define top walls of microchannels 609. Cover plate 610—which, for example, is provided in accordance with conventional practices—has formed therein an inlet port 612 and an outlet port 614. Inlet port 612 is to allow coolant to flow into microchannel chamber 608 and outlet port 614 is to allow coolant to flow out of microchannel chamber 608.

In addition, the fluid conduit includes a manifold plate 616 that is mounted on cover plate 610 to facilitate connection to the fluid conduit of tubing (not shown) for the coolant. In the example embodiment shown, manifold plate 616 is integrated in or on a package 652 for IC die 602. For example, manifold plate 616 forms an upper wall of package 652, which—in turn—forms side walls 654, 656 variously joined both to manifold plate 616 (at respective ends of the manifold plate 616) and also to a package substrate 658 on which IC die 602 is mounted.

Manifold plate 616 is adhered, for example, to the top surface of cover plate 610 by solder or by a sealant 618 such as epoxy or silicone. Manifold plate 616 has a lower horizontal surface 620, a left side vertical surface 622 and a right side vertical surface 624. (As used herein and in the appended claims, a “vertical surface” should be understood to include any surface that departs substantially from the horizontal; and “horizontal” refers to any direction normal to the direction from the fluid conduit to the IC.)

Manifold plate 616 has formed therein an inlet passage 626. Inlet passage 626 provides fluid communication between a port 628 on the lower horizontal surface 620 of manifold plate 616 and a port 630 on left side vertical surface 622. In one such embodiment, inlet passage 626 is a right-angle passage in that it is formed of a vertical course 632 and a horizontal course 634 that joins vertical course 636 at a right angle. (More generally, as used herein and in the appended claims, “right-angle passage” refers to any passage that supports at least an 85° change in flow direction therethrough.) Manifold plate 616 is adhered to cover plate 610 in such a manner that port 628 of manifold plate 616 is aligned with inlet port 612 of cover plate 610. Advantageously, sealant 618 (or alternatively solder, as the case may be) is deployed in such a manner that coolant flows from port 628 to inlet port 612 without leakage.

Manifold plate 616 also has formed therein an outlet passage 636 which facilitates fluid communication between a port 638 on lower horizontal surface 620 of manifold plate 616 and a port 640 on right side vertical surface 624. In the example embodiment shown, outlet passage 636 is a right-angle passage in that it is formed of a vertical course 642 and a horizontal course 644 that joins the vertical course 642 at a right angle. Port 638 of manifold plate 616 is aligned with outlet port 614 of cover plate 610. Sealant 618 (or solder, as the case may be) is deployed in such a manner that coolant flows from outlet port 614 to port 638 without leakage. An upper surface 646 of manifold plate 616, in some embodiments, functions a top surface which extends across package 652.

Manifold plate 616 is formed of a suitable material such as copper, ceramic or polymer. In an embodiment, one or each of passage 626, 636 is formed with two drilling operations—one from horizontal surface 620 and one from vertical surface 622 or 624 as the case may be. In some embodiments a molding process is performed as an alternative to drilling. For example, the manifold plate comprising suitable fittings incorporated therein is formed by molding around metal tubes that constitute the right angle passages and the fittings. The presence of manifold plate 616 as part of the fluid conduit facilitates connection of tubing (for coolant circulation) to the fluid conduit. In one such embodiment, a tube (not shown) leading from a heat exchanger and a pump (both not shown) is connected at port 630 of inlet passage 626 of manifold plate 616. Another tube (not shown) leading to the heat exchanger and the pump is connected at port 640 of outlet passage 636 of manifold plate 616.

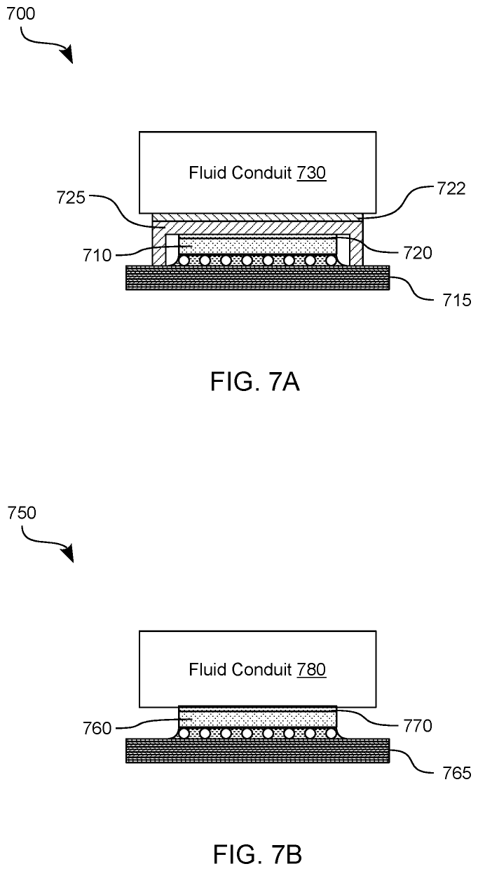

FIGS. 7A and 7B illustrate respective devices 700, 750 which are to variously provide circuit cooling each according to a corresponding embodiment. Devices 700, 750 variously have features of system 100, for example. In some embodiments, functionality of device 700 or device 750 is provided according to method 200—e.g., wherein microchannels of such a device are formed with one or more porous sidewall structures.

FIG. 7A illustrates a “two-TIM” embodiment to facilitate the cooling of a die 710 which, for example, is coupled to a package substrate 715 of a packaged device 700. As illustrated in FIG. 7A, a TIM 720 comprising a first heat conductive material is thermally coupled with die 710, wherein an integrated heat spreader 725 and a second TIM 722 extend between TIM 720 and a fluid conduit 730 of device 700. In an embodiment, fluid conduit 730 comprises features of one of fluid conduits 120, 120a, for example—e.g., wherein microchannels of fluid conduit 730 are formed at least in part by porous sidewall structures as variously described herein.

FIG. 7B illustrates a “single-TIM” embodiment wherein device 750 facilitates cooling of a die 760 which is disposed on a substrate 765. The illustrated cooling structure includes a heat plane 770 which comprises a first thermal material. A fluid conduit 780 of device 750 is adhered or otherwise bonded to heat plane 770—e.g., where fluid conduit 780 has features of one of fluid conduits 120, 120a, for example. In one such embodiment, fluid conduit 780 is packaged with heat plane 770 and die 760.

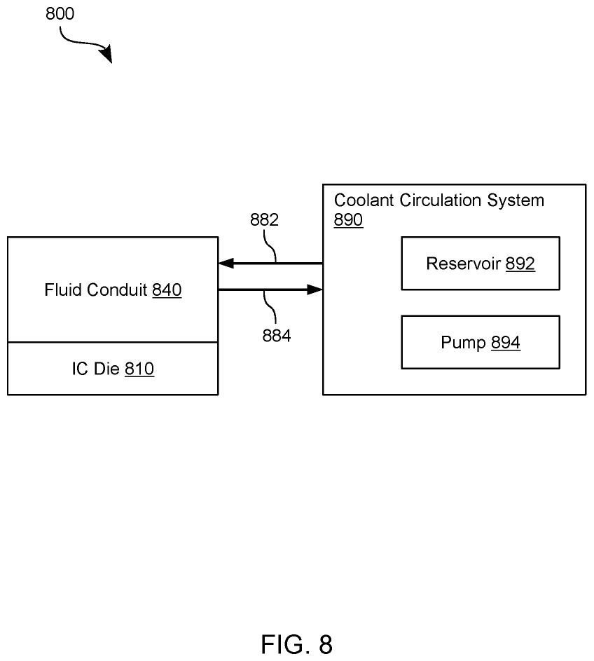

FIG. 8 shows features of a system 800 to provide cooling of circuitry according to an embodiment. In some embodiments, system 800 includes features of system 100, fluid conduit 120a, or one of devices 600, 700, 750—e.g., wherein functionality of system 800 is manufactured or otherwise provided according to method 200.

As shown in FIG. 8, system 800 comprises an IC die 810 and a fluid conduit 840 which is thermally coupled thereto. For purposes of illustration, fluid conduit 840 (which, for example, is any one of the fluid conduits described herein) is shown as a single block. System 800 further comprises a coolant circulation system 890 to supply a coolant fluid to fluid conduit 840. For example, coolant circulation system 890 is in fluid communication with fluid conduit 840 via one or more coolant supply channels 882 and one or more coolant return channels 884.

In the example embodiment shown, coolant circulation system 890 comprises a reservoir 892 of water and/or another suitable coolant fluid. In one such embodiment, coolant circulation system 890 further comprises a pump 894 to generate a pressure differential with which the coolant fluid is circulated—through the one or more supply channels 882 and/or the one or more return channels 884—between reservoir 892 and fluid conduit 840. Coolant supplied by coolant circulation system 890 flows through microchannels of fluid conduit 840 at or above a surface of the IC die 810, to aid in cooling IC die 810. In some embodiments, the coolant is operated with two phases—liquid and vapor. That is, in some embodiments at least part of the coolant in the microchannels is in a gaseous state. In other embodiments, the coolant is single phase—that is, all liquid.

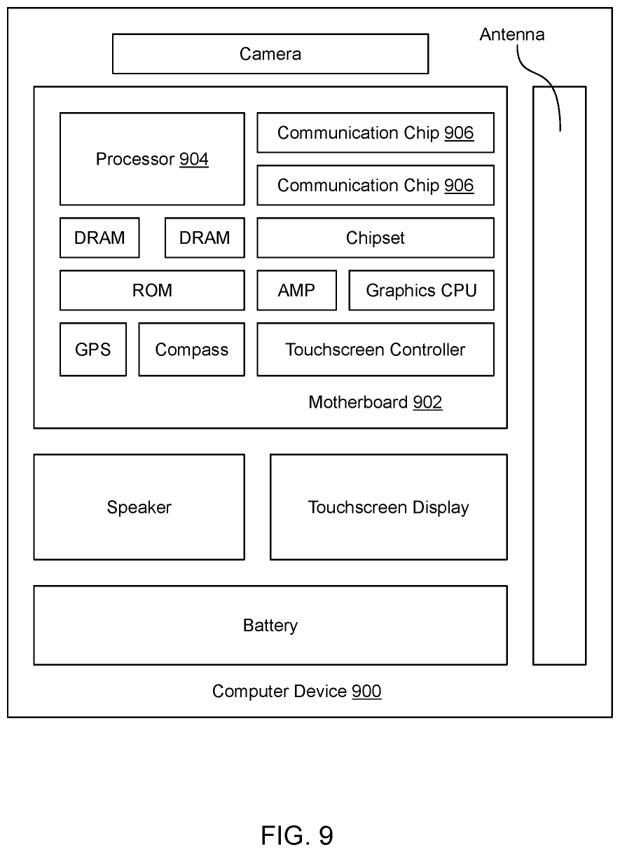

FIG. 9 illustrates a computing device 900 in accordance with one embodiment. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. The term “processor” may refer to any device or portion of a device that processes electronic data from registers and/or memory to transform that electronic data into other electronic data that may be stored in registers and/or memory. The communication chip 906 also includes an integrated circuit die packaged within the communication chip 906.

In various implementations, the computing device 900 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

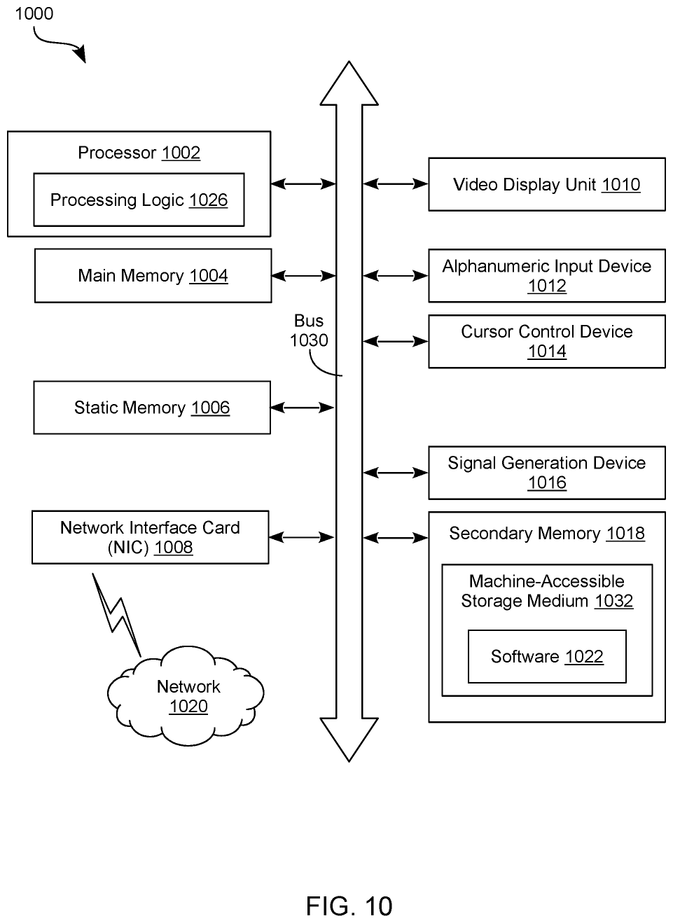

FIG. 10 illustrates a diagrammatic representation of a machine in the exemplary form of a computer system 1000 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 1000 includes a processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

Processor 1002 represents one or more general-purpose processing devices such as a microprocessor, central processing unit, or the like. More particularly, the processor 1002 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 1002 may also be one or more special-purpose processing devices such as an application specific integrated circuit (ASIC), a field programmable gate array (FPGA), a digital signal processor (DSP), network processor, or the like. Processor 1002 is configured to execute the processing logic 1026 for performing the operations described herein.

The computer system 1000 may further include a network interface device 1008. The computer system 1000 also may include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium (or more specifically a computer-readable storage medium) 1032 on which is stored one or more sets of instructions (e.g., software 1022) embodying any one or more of the methodologies or functions described herein. The software 1022 may also reside, completely or at least partially, within the main memory 1004 and/or within the processor 1002 during execution thereof by the computer system 1000, the main memory 1004 and the processor 1002 also constituting machine-readable storage media. The software 1022 may further be transmitted or received over a network 1020 via the network interface device 1008.

While the machine-accessible storage medium 1032 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

Techniques and architectures for regulating the temperature of circuitry are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A fluid conduit for cooling an integrated circuit (IC) die, comprising:
a base to conduct heat from the IC die; and
a plurality of microchannels over the base, the plurality of microchannels comprising first ends coupled to an inlet of the fluid conduit, and second ends coupled to an outlet of the fluid conduit, the plurality of microchannels to convey a fluid in parallel over the base, wherein the plurality of microchannels comprises a first microchannel and a second microchannel in fluid communication with each other through one or more pores of a sidewall structure therebetween.

2. The fluid conduit of claim 1, wherein the sidewall structure spans a longitudinal length over the base between respective ends of the first microchannel and the second microchannel, and the sidewall structure comprises a plurality of pores over at least half the longitudinal length.

3. The fluid conduit of claim 1, wherein for each of the one or more pores of the sidewall structure, a cross sectional area of the pore is less than a cross sectional area of one of the first microchannel or the second microchannel.

4. The fluid conduit of claim 1, wherein the first microchannel and the second microchannel are to convey the fluid along a first dimension over a surface of the base, and the sidewall structure provides a porosity gradient along a second dimension which is orthogonal to the first dimension.

5. The fluid conduit of claim 4, wherein a first portion of the sidewall structure is disposed between the base and a second portion of the sidewall structure, wherein the first portion is less porous than the second portion.

6. The fluid conduit of claim 1, wherein the first microchannel and the second microchannel are to convey the fluid along a first dimension over a surface of the base, and the sidewall structure provides a porosity gradient along the first dimension.

7. The fluid conduit of claim 1, wherein a porosity of the sidewall structure is between 5% and 50%.

8. The fluid conduit of claim 1, wherein a width of the sidewall structure between the first microchannel and the second microchannel is in a range of 20 micrometers (μm) to 2000 μm.

9. The fluid conduit of claim 1, wherein multiple sidewall structures are each disposed between a respective two microchannels of the plurality of microchannels, wherein, for each of the multiple sidewall structures, pores extend through to the sidewall structure to opposite respective sides of the sidewall structure.

10. The fluid conduit of claim 1, wherein the base comprises one of copper or aluminum.

11. A device comprising:
a package substrate;
an integrated circuit (IC) die coupled to the package substrate; and
a fluid conduit thermally coupled to the IC die, the fluid conduit comprising:
a base to conduct heat from the IC die; and
a plurality of microchannels over the base, the plurality of microchannels comprising first ends coupled to an inlet of the fluid conduit, and second ends coupled to an outlet of the fluid conduit, the plurality of microchannels to convey a fluid in parallel over the base, wherein the plurality of microchannels comprises a first microchannel and a second microchannel in fluid communication with each other through one or more pores of a sidewall structure therebetween.

12. The device of claim 11, wherein the sidewall structure spans a longitudinal length over the base between respective ends of the first microchannel and the second microchannel, and the sidewall structure comprises a plurality of pores over at least half the longitudinal length.

13. The device of claim 11, wherein the first microchannel and the second microchannel are to convey the fluid along a first dimension over a surface of the base, and the sidewall structure provides a porosity gradient along a second dimension which is orthogonal to the first dimension.

14. The device of claim 13, wherein a first portion of the sidewall structure is disposed between the base and a second portion of the sidewall structure, wherein a first vertical span of the first portion, and a second vertical span of the second portion are each at least 10% of a total vertical span of the sidewall structure, and wherein a first porosity of the first portion differs from a second porosity of the second portion by at least 5%.

15. The device of claim 11, wherein the first microchannel and the second microchannel are to convey the fluid along a first dimension over a surface of the base, and the sidewall structure provides a porosity gradient along the first dimension.

16. The device of claim 11, wherein multiple sidewall structures are each disposed between a respective two microchannels of the plurality of microchannels, wherein, for each of the multiple sidewall structures, pores extend through to the sidewall structure to opposite respective sides of the sidewall structure.

17. A system comprising:
an integrated circuit (IC) die;
a fluid conduit thermally coupled to the IC die, the fluid conduit comprising:
a base to conduct heat from the IC die; and
a plurality of microchannels over the base, the plurality of microchannels comprising first ends coupled to an inlet of the fluid conduit, and second ends coupled to an outlet of the fluid conduit, the plurality of microchannels to convey a fluid in parallel over the base, wherein the plurality of microchannels comprises a first microchannel and a second microchannel in fluid communication with each other through one or more pores of a sidewall structure therebetween; and
a display device coupled to the IC die, the display device to display an image based on a signal from the IC die.

18. The device of claim 17, wherein the sidewall structure spans a longitudinal length over the base between respective ends of the first microchannel and the second microchannel, and the sidewall structure comprises a plurality of pores over at least half the longitudinal length.

19. The device of claim 17, wherein the first microchannel and the second microchannel are to convey the fluid along a first dimension over a surface of the base, and the sidewall structure provides a porosity gradient along a second dimension which is orthogonal to the first dimension.

20. The device of claim 17, wherein multiple sidewall structures are each disposed between a respective two microchannels of the plurality of microchannels, wherein, for each of the multiple sidewall structures, pores extend through to the sidewall structure to opposite respective sides of the sidewall structure.
